(19) United States
(12) Patent Application Publication
(10) Pub. No.: US 2007/0023922 A1
(43) Pub. Date: Feb. 1, 2007

(54) Semiconductor package

(75) Inventors: Noboru Okane, Yokkaichi-shi (JP); Ryoji Matsushima, Yokkaichi-shi (JP); Kazuhiro Yamamori, Yokkaichi-shi (JP); Junya Sagara, Kawasaki-shi (JP); Yoshio Iizuka, Yokohama-shi (JP); Kuniyuki Oonishi, Kawasaki-shi (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Minato-ku (JP)

(21) Appl. No.: 11/490,022

(22) Filed: Jul. 21, 2006

(30) Foreign Application Priority Data
Jul. 26, 2005 (JP) P2005-216167

(51) Int. Cl. H01L 23/48

(52) U.S. Cl. 257/778

(57) ABSTRACT

A semiconductor package includes a circuit board having connection pads formed on a front and back surfaces, and a wiring network connected to these connection pads, as a package base. Metal bumps connected to at least part of the connection pads on the front and back surfaces via the wiring network are formed on the back surface of the circuit board as external connection terminals. One or a plurality of semiconductor elements electrically connected to the connection pad on the front surface side is or are mounted on a first element mounting part provided on the front surface side of the circuit board. One or plurality of semiconductor elements electrically connected to the connection pad on the back surface side is or are mounted on a second element mounting part provided on the back surface side of the circuit board.

### CROSS-REFERENCE TO RELATED APPLICATIONS

This application is based upon and claims the benefit of priority from the prior Japanese Patent Application No. 2005-216167, filed on Jul. 26, 2005; the entire contents of which are incorporated herein by reference.

### BACKGROUND

1. Field of the Invention

The present invention relates to a semiconductor package.

2. Description of the Related Art

In order to realize miniaturization, high density mounting and the like of a semiconductor device, a stacked multichip package in which a plurality of semiconductor elements are stacked and sealed in one package have been put to practical use in recent years. In such a stacked multichip package, a plurality of semiconductor elements are stacked in sequence on a circuit board. An electrode pad of each of the semiconductor elements are electrically connected to a connection pad of a circuit board via a bonding wire. By packaging such a stacked structure with a sealing resin, a stacked multichip package is constructed.

As a connecting structure to an external board in a stacked multichip package, a BGA structure in which solder balls and the like are formed as external connection terminals on a back surface side of a circuit board with a semiconductor element mounted thereon is generally used (for example, see JP-A 2003-179200 (KOKAI), JP-A 2004-072009 (KOKAI), and JP-A 2004-193363 (KOKAI)).

In the semiconductor package to which such a BGA structure is applied, the package size is reduced by forming the solder balls as the external connection terminals on the entire back surface of the circuit board. Namely, a circuit board having an area on which a mounting part of the semiconductor element and a connection pad around it are capable of being disposed is used as an element mounting substrate. By forming the solder balls on the entire back surface including the area directly under the element of such a circuit board, increase in package size is prevented.

However, in the conventional stacked multichip package, a plurality of semiconductor elements are mounted by being stacked on only the front surface side of a circuit board, and therefore, there is a limit to increase in the number of semiconductor elements which are stacked while maintaining thin package. Further reduction in thickness is required depending on the use of semiconductor package, but the conventional stacked multichip package inevitably increases in thickness of the package corresponding to the number of stacked semiconductor elements. Semiconductor packages are required to respond to large capacity memory devices, logic products for control and the like, and therefore, a further increase in the number of semiconductor elements which are stacked and reduction in thickness are desired.

### SUMMARY

A semiconductor package according to an embodiment of the present invention comprises a package base including a circuit board having a first connection pad formed on a front surface, a second connection pad formed on a back surface and a wiring network connected to the first and second connection pads, a first element mounting part provided on the front surface side of the circuit board, a second element mounting part provided on the back surface side of the circuit board, and external connection terminals having metal bumps which are provided on the back surface of the circuit board to surround the second element mounting part and are connected to at least part of the first and second connection pads via the wiring network; a first element group which is mounted on the first element mounting part of the package base, and has at least one semiconductor element electrically connected to the first connection pad; and a second element group which is mounted on the second element mounting part of the package base, and has at least one semiconductor element electrically connected to the second connection pad.

A semiconductor package according to another embodiment of the present invention comprises a package base including a circuit board having a first connection pad formed on a front surface, a second connection pad formed on a back surface, and a wiring network connected to the first and second connection pads, a first element mounting part provided on the front surface side of the circuit board, a second element mounting part provided on the back surface side of the circuit board, and external connection terminals having metal bumps which are provided on the back surface of the circuit board to surround the second element mounting part and are connected to at least part of the first and second connection pads via the wiring network; a first element group which is mounted on the first element mounting part of the package base, and has a first semiconductor element electrically connected to the first connection pad via a first bonding wire and a second semiconductor element stacked on the first semiconductor element and electrically connected to the first connection pad via a second bonding wire; and a second element group which is mounted on the second element mounting part of the package base, and has a third semiconductor element electrically connected to the second connection pad via a third bonding wire and a fourth semiconductor element stacked on the third semiconductor element and electrically connected to the second connection pad via a fourth bonding wire.

A semiconductor package according to still another embodiment of the present invention comprises a package base including a circuit board having a first connection pad formed on a front surface, a second connection pad formed on a back surface, and a wiring network connected to the first and second connection pads, a first element mounting part provided on the front surface side of the circuit board, a second element mounting part provided on the back surface side of the circuit board, and external connection terminals having metal bumps which are provided on the back surface of the circuit board to surround the second element mounting part and are connected to at least part of the first and second connection pads via the wiring network; a first element group which is mounted on the first element mounting part of the package base, and has at least one semiconductor element electrically connected to the first connection pad; and a second element group which is mounted on the second element mounting part of the package base, and has a semiconductor element electrically connected to the second connection pad and smaller than the semiconductor element constituting the first element group.

### BRIEF DESCRIPTION OF THE DRAWINGS

FIG. 1 is a sectional view showing a construction of a semiconductor package by a first embodiment of the present invention.

FIG. 2 is a sectional view showing a part of the semiconductor package shown in FIG. 1 by enlarging it.

FIG. 3 is a sectional view showing apart of the semiconductor package shown in FIG. 1 by enlarging it.

FIG. 4 is a sectional view showing a modified example of the semiconductor package shown in FIG. 1.

FIG. 5 is a sectional view showing a semiconductor package according to a second embodiment of the present invention.

FIG. 6 is a sectional view showing a modified example of the semiconductor package shown in FIG. 5.

### DETAILED DESCRIPTION

Embodiments of the present invention will now be described with reference to the drawings. The embodiments of the present invention will be described based on the drawings hereinafter, but the drawings are provided for only illustration, and the present invention is not limited to these drawings.

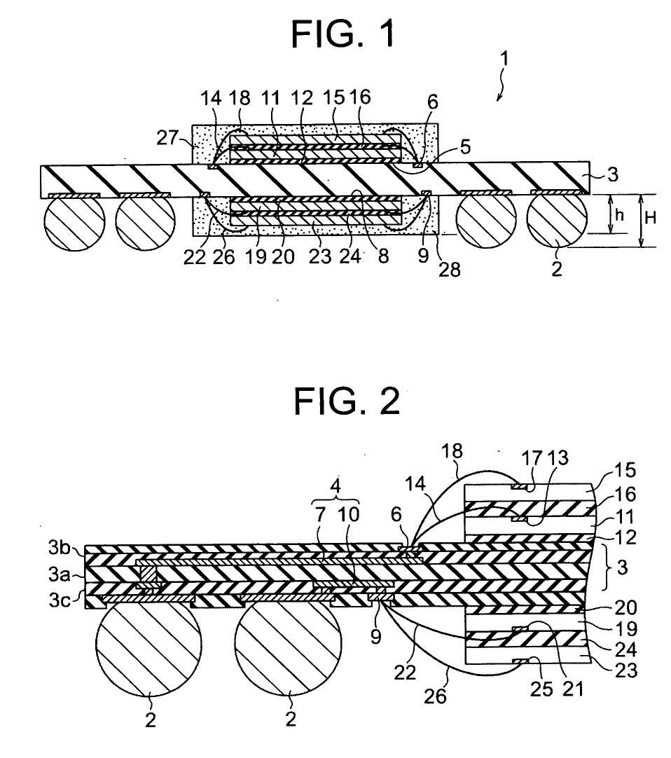

FIG. 1 is a sectional view showing a construction of a semiconductor package of a BGA structure according to a first embodiment of the present invention, and FIG. 2 is a sectional view showing a part of the semiconductor package by enlarging it. A semiconductor package 1 shown in these drawings includes a circuit board 3 having external connection terminals 2, as a package base. The external connection terminal 2 is constructed by a metal bump. The circuit board 3 is providing with a wiring network 4 inside and on a front surface of various kinds of insulating substrates such as a resin substrate, a ceramics substrate, and a glass substrate, and more specifically, a multilayer printed wiring board using a glass-epoxy resin, a BT resin (Bismaleimide-triazine resin) and the like can be applied.

A first element mounting part 5 is provided on a front surface side of the circuit board 3, and a first connection pad 6 is formed in its periphery. The first connection pad 6 is to be a bonding part at the time of wire bonding, and is electrically connected to a metal bump 2 via an internal wiring (including a via, an internal wiring layer, a through-hole and the like) 7 of the circuit board 3. Meanwhile, on a back surface side of the circuit board 3, a second element mounting part 8 is provided, a second connection pad 9 is formed in its periphery. The second connection pad 9 is electrically connected to the metal bump 2 via an internal wiring (including a via, an internal wiring layer and the like) 10 of the circuit board.

The circuit board 3 has the element mounting parts 5 and 8 and the connection pads 6 and 9 respectively on the front and the back surfaces. Further, the connection pads 6 and 9 on the front and back surfaces are electrically connected to the metal bumps 2 via the independent internal wirings 7 and 10 respectively. The circuit board 3 shown in FIG. 2 has a core board 3 a having a through-hole and buildup layers 3b and 3c formed on both surfaces thereof.

The buildup layer 3b constructs the internal wiring 7 for the first connection pad 6. The buildup layer 3c constructs the internal wiring 10 of the second connection pad 9. Namely, wirings for the external connection terminals (metal bumps 2) extend to the connection pads 6 and 9 provided on both the front and back surfaces of the circuit board 3, and have independent electric wiring functions respectively.

The metal bumps 2 as the external connecting terminals are provided on the back surface of the circuit board 3 to surround the second element mounting part 8 and the second connection pad 9. By disposing the metal bumps 2 on the outer periphery side of the back surface of the circuit board 3 like this, it becomes possible to place the second element mounting part 8 on the back surface side of the circuit board 3 while applying an external connection structure (BGA structure) using the metal bumps 2. The metal bump 2 is generally formed by a solder ball, but is not limited to this, and it may be constructed by other low-melting metal balls when occasion demands.

A first semiconductor element 11 is bonded onto the first element mounting part 5 of the circuit board 3 via a first bonding layer 12. A die attach material of an ordinary insulating resin can be applied as the first bonding layer 12. A first electrode pad 13 provided on a top surface side of the first semiconductor element 11 is connected to the first connection pad 6 via a first bonding wire 14.

Further, a second semiconductor element 15 is bonded onto the first semiconductor element 11 via a second bonding layer 16. The second bonding layer 16 is composed of an insulating resin which functions as an adhesive. A second electrode pad 17 which is provided at a top surface side of the second semiconductor element 15 is connected to the first connection pad 6 via a second bonding wire 18. These first and the second semiconductor elements 11 and 15 constitute a first element group.

A third semiconductor element 19 is bonded onto the second element mounting part 8 of the circuit board 3 via a third bonding layer 20. The third bonding layer 20 is similar to the first bonding layer 12. A third electrode pad 21 provided at a top surface side of the third semiconductor element 19 is connected to the second connection pad 9 via a third bonding wire 22.

Further, a fourth semiconductor element 23 is bonded onto the third semiconductor element 19 via a fourth bonding layer 24. The fourth bonding layer 24 is composed of an insulating resin which functions as an adhesive similarly to the second bonding layer 16. A fourth electrode pad 25 which is provided at a top surface side of the fourth semiconductor element 23 is connected to the second connection pad 9 via a fourth bonding wire 26. The third and the fourth semiconductor elements 19 and 23 constitute a second element group.

On the front surface side of the circuit board 3, the first and second semiconductor elements 11 and 15 including the bonding wires 14 and 18 are sealed with a first sealing resin 27 composed of an epoxy resin or the like. Likewise, on the back surface side of the circuit board 3, the third and the fourth semiconductor elements 19 and 23 including the bonding wires 22 and 26 are sealed with a second sealing resin 28. The semiconductor package 1 of the BGA structure is constructed by them. A height h of the second sealing resin 28 is set to be lower than a height H of the metal bump 2 (h<H).

In the semiconductor package 1 of this embodiment, the metal bumps 2 as the external connection terminals are disposed at the outer periphery side of the back surface of the circuit board 3, and therefore, not only the semiconductor elements can be stacked and mounted on the front surface side of the circuit board 3, but also the semiconductor elements 19 and 23 can be stacked and mounted on the back surface side. According to this embodiment, the number of semiconductor elements which are mounted can be increased, and therefore, it becomes possible to provide the semiconductor package 1 corresponding to, for example, a large capacity memory device.

Further, the thickness by the semiconductor elements 19 and 23 on the back surface side is kept within the height of the metal bump 2 as the external connection terminal. Accordingly, the number of semiconductor elements which are mounted can be increased by the number of the semiconductor elements 19 and 23 which are mounted on the back surface side while keeping the thickness equivalent to the conventional semiconductor package mounted with the semiconductor elements on only the front surface side of the circuit board. Namely, it becomes possible to increase the number of semiconductor elements which are mounted while keeping the small thickness of the semiconductor package 1.

In the above described semiconductor package 1, as for the shapes of the first semiconductor element 11 and the second semiconductor element 15, and the shapes of the third semiconductor element 19 and the fourth semiconductor element 23, those on the upper side are made smaller than those on the lower side, or they are respectively formed into substantially the same shapes. When the semiconductor elements which are stacked are in substantially the same shape, the second and fourth semiconductor elements 15 and 23 exist on the first and third bonding wires 14 and 22, and therefore, it is important to prevent them from contacting each other.

Thus, insulating resins which function as the second and fourth bonding layers 16 and 24 are preferably charged between the respective elements (between the first and second semiconductor elements 11 and 15, and between the third and the fourth semiconductor elements 19 and 23). In keeping the space between the respective elements, it is conceivable to dispose spacers smaller than the respective elements between the respective elements, for example. However, if the smaller spacers than the respective elements are disposed, areas below the electrode pads 17 and 25 of the second and fourth semiconductor elements 15 and 23 are in the hollow state.

In such a case, there is the fear of occurrence of bending to the second and fourth semiconductor elements 15 and 23 due to bonding load. Bending of the second and fourth semiconductor elements 15 and 23 due to bonding load becomes a cause of occurrence of poor bonding of the second and fourth bonding wires 18 and 26, connection failure of the first and third bonding wires 14 and 22, cracking of the second and fourth semiconductor elements 15 and 23, and the like.

In this embodiment, the insulating resin which functions as the second bonding layer 16 is charged between the first semiconductor element 11 and the second semiconductor element 15. Similarly, the insulating resin which functions as the fourth bonding layer 24 is charged between the third semiconductor element 19 and the fourth semiconductor element 23. A connecting side end portion (element side end portion) of the first bonding wire 14 to the first semiconductor element 11 is buried in the insulating resin layer (the second bonding layer 16). A connecting side end portion (element side end portion) of the third bonding wire 22 to the third semiconductor element 19 is buried in the insulating resin layer (the fourth bonding layer 24).

By charging the insulating resin layers (the second and fourth bonding layers 16 and 24) between the stacked semiconductor elements 11 and 15, and between the semiconductor elements 19 and 23 as above, bending of the second and the fourth bonding wires 18 and 26 due to bonding load can be restrained. Thereby, it becomes possible to restrain poor bonding, contact with the bonding wires 14 and 22 on the lower side, deformation of the bonding wires 14 and 22, cracking and breakage of the semiconductor elements 15 and 23, and the like.

Further, by restraining bending of the semiconductor elements 15 and 23 with the insulating resin layers 16 and 24, the thickness of the semiconductor elements 15 and 23 can be made thin. Specifically, the thickness of the semiconductor elements 15 and 23 can be made 70 μm or less. Accordingly, it becomes possible to make the semiconductor package 1 thinner. Further, the element side end portions of the first and third bonding wires 14 and 22 are buried in the insulating resin layers 16 and 24, and therefore, occurrence of connection failure due to peeling-off or the like of the connecting portions of the first and third bonding wires 14 and 22 in the subsequent manufacturing process steps, the transfer process and the like can be restrained.

The space between the first semiconductor element 11 and the second semiconductor element 15, and the space between the third semiconductor element 19 and the second semiconductor element 23 are respectively kept with the insulating resin layers 16 and 24. Therefore, it is important to prevent contact of the bonding wires 14 and 22 on the lower side and the semiconductor elements 15 and 23 on the upper side when the semiconductor elements 15 and 23 on the upper side are bonded onto the semiconductor elements 11 and 19 on the lower side. Contact of these bonding wires 14 and 22 and the semiconductor elements 15 and 22 can be prevented by making the thickness of the bonding layers (insulating resin layers) 16 and 24 larger than the height of the bonding wires 14 and 22 (height on the elements).

In the semiconductor package shown in FIGS. 1 and 2, the bonding wires 14 and 22 are spaced from the lower surfaces of the semiconductor elements 15 and 23 on the upper side based on the thickness of the bonding layers (insulating resin layers) 16 and 24. Occurrence of insulation failure, short-circuiting and the like due to contact of the bonding wires 14 and 22 with the semiconductor elements 15 and 23 can be prevented based on the thickness of the insulating resin layers 16 and 24. However, when the contact prevention effect is to be obtained with such a structure, the insulating resin layers 16 and 24 sometimes become unnecessarily thick depending on the set thickness. This increases the thickness as the entire semiconductor package 1.

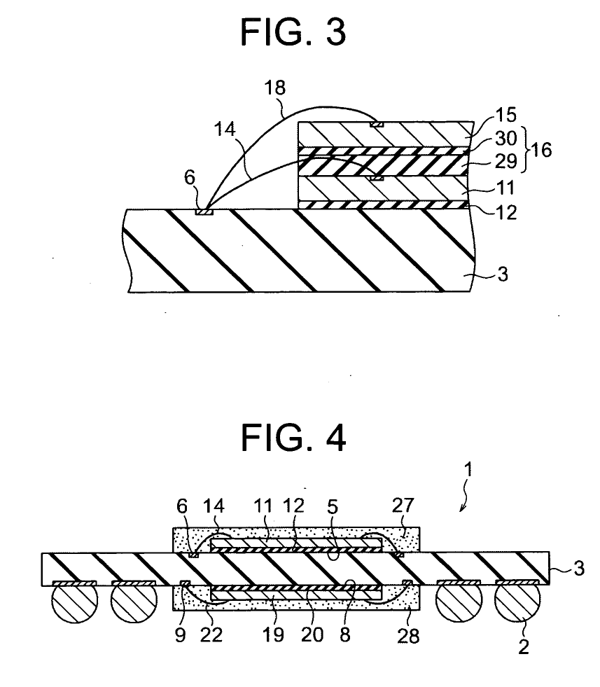

In this respect, the second bonding layer 16 that has a first resin layer 29 which is softened or melted at a bonding temperature of the second semiconductor element 15, and a second resin layer 30 with its layer shape maintained against the bonding temperature of the second semiconductor element 15 as shown in FIG. 3 is effective. Though not shown in FIG. 3, the fourth bonding layer 24 is preferably made to have the similar two-layer structure. Here, a bonding structure of the first semiconductor element 11 and the second semiconductor element 15 is mainly described, and the bonding structure of the third semiconductor element 19 and the fourth semiconductor element 23 is the same.

In the bonding layer 16 of the two-layer structure, the first resin layer 29 is disposed at the first semiconductor element 11 side, and functions as an adhesive layer at the time of bonding the second semiconductor element 15. The first resin layer 29 is softened or melted at the bonding temperature, and makes it possible to entrap the first bonding wire 14. Meanwhile, the second resin layer 30 is disposed at the second semiconductor element 15 side, and maintains the layer shape at the time of bonding the second semiconductor element 15 to function as an insulating layer. The second resin layer 30 has the function of preventing occurrence of insulation failure, short-circuiting and the like due to contact of the bonding wire 14 and the second semiconductor element 15.

In the bonding layer 16 of the two-layer structure, the thickness of the first resin layer 29 is preferably set properly in accordance with the height of the first bonding wire 14. When the height of the first bonding wire 14 (the maximum height on the first semiconductor element 11) is set at 60±15 μm, the thickness of the first resin layer 29 which is softened or melted at the bonding temperature is preferably set at, for example, 75±15 μm. Meanwhile, the thickness of the second resin layer 30 which maintains the layer shape against the bonding temperature is preferably set in the range of, for example, 5 to 15 μm. By applying the bonding layer 16 of such thickness, further reduction in thickness of the semiconductor package 1 can be realized.

In order to exhibit the function of each of the resin layers 29 and 30 favorably, the viscosity of the first resin layer 29 at the bonding temperature (bonding viscosity) is preferably 1 kpa·s to 100 kpa·s inclusive. The first resin layer 29 is too soft if its bonding viscosity is less than 1 kpa·s, and there is the fear of the adhesive resin lies off the element end surface. If the bonding viscosity of the first resin layer 29 exceeds 100 kpa·s, the first resin layer 29 is too hard, and there arises the fear of causing deformation, connection failure and the like of the first bonding wire 14. The bonding viscosity of the first resin layer 29 is more preferably in the range of 1 to 50 kpa·s.

The second resin layer 30 preferably has viscosity at the bonding temperature (bonding viscosity) of 130 kpa·s or more. When the bonding viscosity of the second resin layer 30 is less than 130 kpa·s, the layer shape cannot be maintained when the second semiconductor element 15 is bonded to the first semiconductor element 11, and loses the function as the insulating layer of the second resin layer 30. The bonding viscosity of the second resin layer 30 is preferably 1000 kpa·s or less.

The above described bonding layer 16 of the two-layer structure can be obtained by stacking the first resin layer 29 which is constituted of an epoxy resin layer controlled to be softened or melted at, for example, the bonding temperature, and the second resin layer 30 which is constituted of a polyimide resin layer, a silicon resin layer or the like of which layer shape is maintained against the bonding temperature to form an adhesive film of the two-layer structure, and by attaching this onto the back surface (bonding surface) side of the second semiconductor element 15 in advance.

However, when the adhesive film of the two-layer structure of different materials is used, there arises the fear of causing peeling-off of the elements after the bonding step of the second semiconductor element 15 based on the difference in thermal expansion coefficient between the first resin layer 29 and the second resin layer 30 and the like, an increase in manufacturing cost required for bonding, and the like. Thus, the insulating resins of the same material are preferably applied to the first and second resin layers 29 and 30 which constitute the bonding layer 16 of the two-layer structure. As such an insulating resin, a thermosetting resin as, for example, an epoxy resin is cited.

When the first resin layer 29 and the second resin layer 30 are formed of the same material, a difference can be given to the behavior (function) at the bonding time by making the drying temperature and drying time when forming the first resin layer 29 and the second resin layer 30 different by using, for example, the same thermosetting resin vanish. Namely, the first resin layer 29 which functions as a softening or melting layer, and the second resin layer 30 which functions as an insulating layer can be obtained with the insulating resin of the same material.

For example, after the epoxy resin vanish (A stage) is coated on the substrate, the coating layer is dried at 150° C. to form the second resin layer 30 in a half cured state (B stage). Subsequently, the same epoxy resin vanish (A stage) is coated on the second resin layer 30 again, and the coating layer is dried at 130° C. to form the first resin layer 29 in the half cured state (B stage). Such a resin layer of the two-layer structure is peeled off from the substrate and used as an adhesive film. The adhesive film of the two-layer structure is preferably used by being attached to the back surface (bonding surface) side of the second semiconductor element 15 in advance.

When the adhesive film is heated at a temperature which is not lower than the drying temperature of the first resin layer 29 (130° C. or higher) and lower than the drying temperature of the second resin layer 30 (lower than 150° C.), the second resin layer 30 has its layer shape maintained, while only the first resin layer 29 is softened or melted. Therefore, by setting the bonding temperature of the second semiconductor element 15 in the temperature range as described above (for example, from 130° C. to 150° C.), the first resin layer 29 can be softened or melted while the second resin layer 30 is caused to function as the insulating layer.

In FIGS. 1 and 2, the structure in which the two semiconductor elements are stacked on each of both the front and back surfaces of the circuit board 3 is described, but the number of semiconductor elements which are stacked is not limited to this, and the number of elements which are stacked may be three or more. Further, the structure is not limited to the structure in which a plurality of semiconductor elements are stacked on both the front and back surfaces of the circuit board 3, and it is also possible to apply the structure in which one semiconductor element is mounted on either one of the element mounting parts of the circuit board 3. Like this, the number of semiconductor elements which are mounted on both the front and back surfaces of the circuit board 3 can be properly set in accordance with the application apparatus, use purpose and the like.

Further, the number of semiconductor elements which are mounted on each of both the front and back surfaces of the circuit board 3 may be one, as shown in FIG. 4, for example. Namely, the semiconductor package 1 may have the structure in which only the semiconductor element 11 is mounted on the first element mounting part 5 of the circuit board 3 and only the semiconductor element 19 is mounted on the second element mounting part 8. In the semiconductor package 1 having such an element mounting structure, the thickness due to the semiconductor element 19 on the back surface side is kept within the height of the metal bump 2, and therefore, it becomes possible to further reduce the package thickness while the function as the multichip package is obtained.

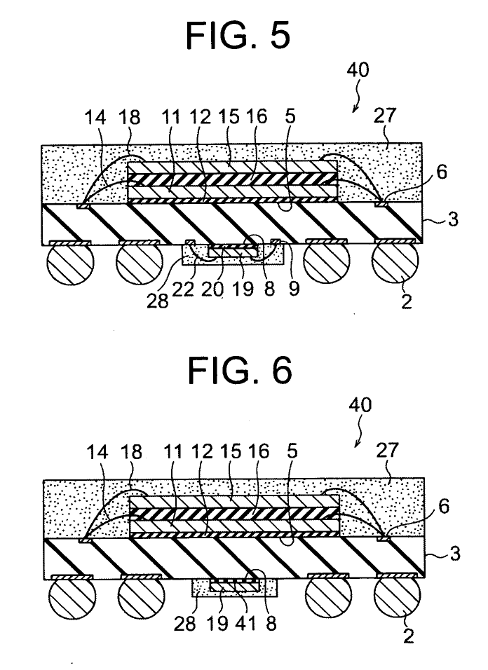

Next, a semiconductor package according to a second embodiment of the present invention will be described with reference to FIG. 5. FIG. 5 is a sectional view showing a construction of the semiconductor package according to the second embodiment. The same parts as the above described first embodiment are assigned with the same reference numerals and characters, and the explanation of them will be partially omitted.

A semiconductor package 40 shown in FIG. 5 has a BGA structure as in the first embodiment, and includes the circuit board 3 having the metal bumps 2, as a package base. The first element mounting part 5 is provided on the front surface side of the circuit board 3, and the first connection pad 6 is further formed in its periphery. The first connection pad 6 is electrically connected to the bump 2 via the internal wiring (not shown) of the circuit board 3. The second element mounting part 8 is provided on the back surface side of the circuit board 3, and the second connection pad 9 is formed in its periphery. The second connection pad 9 is electrically connected to the metal bump 2 via the internal wiring (not shown) of the circuit board. The concrete structure of the circuit board 3 is as shown in FIG. 2.

The first semiconductor element 11 is bonded onto the first element mounting part 5 of the circuit board 3 via the first bonding layer 12. The first semiconductor element 11 is connected to the first connection pad 6 via the first bonding wire 14. Further, the second semiconductor element 15 is bonded onto the first semiconductor element 11 via the second bonding layer 16. The second semiconductor element 15 is connected to the first connection pad 6 via the second bonding wire 18. The first and second semiconductor elements 11 and 15 constitute a first element group, and as its concrete example, a memory element of a NAND type flush memory or the like is cited.

The second bonding layer 16 is constituted of an insulating resin which functions as an adhesive as in the first embodiment, and its concrete structures (the charge structure, the layer structure, the composing structure and the like) are preferably made the same as in the first embodiment. The insulating structure of the first bonding wire 14 and the second semiconductor element 15 is preferably made the same as in the first embodiment, and its concrete structure is as described above. The element side end portion of the first bonding wire 14 is buried in the second bonding layer (insulating resin layer) 16. The first bonding wire 14 is insulated from the second semiconductor element 15 based on the insulating resin layer 16.

Meanwhile, only the third semiconductor element 19 is bonded onto the second element mounting part 8 of the circuit board 3 via the third bonding layer 20. The third semiconductor element 19 is connected to the second connection pad 9 via the third bonding wire 22. The second element group in the semiconductor package 40 of the second embodiment is constituted of the semiconductor element 19 which is smaller than the first and second semiconductor elements 11 and 15. As a concrete example of such a semiconductor element 19, a controller element for the first and second semiconductor elements 11 and 15 as memory elements is cited.

The structure in which the first and second semiconductor elements 11 and 15 as memory elements are connected to the semiconductor element 19 as a controller element via the internal wiring of the circuit board 3 may be adopted. In this case, access to the first and second semiconductor elements 11 and 15 from an outside is performed via the semiconductor element 19. Namely, only the second connection pad 9 provided at the back surface side of the circuit board 3 is electrically connected to the metal bump 2. The metal bump 2 is connected to at least part of the first connection pad 6 provided on the front surface side of the circuit board 3 and the second connection pad 9 provided on the back surface side.

By mounting the semiconductor element 19, which is smaller than the semiconductor elements 11 and 15 on the front surface side, on the back surface side of the circuit board 3, the area of the element mounting part 8 in the back surface of the circuit board 3 can be reduced. Accordingly, it becomes possible to dispose the metal bumps 2 as in an ordinary package. In other words, by mounting the small semiconductor element 19 on the back surface side of the circuit board 3, the disposition area for the metal bumps 2 as the external connection terminals can be ensured even in the case of using the circuit board 3 having the shape and the size corresponding to the semiconductor elements 11 and 15 on the front surface side.

Namely, the metal bumps 2 are disposed around the second element mounting part 8 and the second connection pad 9, but the disposition area is kept within the circuit board 3 corresponding to the semiconductor elements 11 and 15 on the front surface side. Accordingly, the semiconductor package 40 in which the number of semiconductor elements which are mounted is increased while an increase in package size is restrained can be provided. In other words, it becomes possible to increase the number of semiconductor elements which are mounted by the semiconductor element 19 which is mounted on the back surface side while keeping the size and the thickness of the semiconductor package.

The concrete construction of the metal bump 2 and the circuit board 3, the mounting structure of the semiconductor elements 11, 15 and 19 (including the height h or the like), the bonding structure of the stacked semiconductor elements 11 and 15, the connecting structure of the bonding wires 14, 18 and 22, and the like are preferably made the same as the above described first embodiment. The connecting structure of the semiconductor element 19 which is mounted on the back surface side of the circuit board 3 and the circuit board 3 is not limited to the wire bonding connection, but, for example, flip chip connection as shown in FIG. 6 may be applied. In FIG. 6, reference numeral 41 designates a metal bump for flip chip connection. Further, the number of semiconductor elements which are mounted on the front surface side of the circuit board 3 is not limited to two, and three or more of semiconductor elements may be stacked and mounted.

The present invention is not limited to the above described embodiments, but can be applied to various kinds of BGA packages on each of which one or a plurality of semiconductor elements is or are mounted on both surfaces of the circuit board. Such semiconductor packages are also included in the present invention. The embodiments of the present invention can be expanded or modified within the scope of the technical idea of the present invention, and the expanded or modified embodiment is also included in the technical range of the present invention.

What is claimed is:

1. A semiconductor package, comprising:
a package base including a circuit board having a first connection pad formed on a front surface, a second connection pad formed on a back surface, and a wiring network connected to the first and second connection pads, a first element mounting part provided on the front surface side of the circuit board, a second element mounting part provided on the back surface side of the circuit board, and external connection terminals having metal bumps which are provided on the back surface of the circuit board to surround the second element mounting part and are connected to at least part of the first and second connection pads via the wiring network;
a first element group which is mounted on the first element mounting part of the package base, and has at least one semiconductor element electrically connected to the first connection pad; and
a second element group which is mounted on the second element mounting part of the package base, and has at least one semiconductor element electrically connected to the second connection pad.

2. The semiconductor package according to claim 1,
wherein at least one of the first and second element groups has a plurality of the semiconductor elements which are stacked.

3. The semiconductor package according to claim 2,
wherein the plurality of the stacked semiconductor elements are bonded to each other via an insulating resin layer.

4. The semiconductor package according to claim 3
wherein the plurality of semiconductor elements are electrically connected to the first connection pad or the second connection pad via bonding wires respectively, and an element side end portion of the bonding wire connected to the semiconductor element on a lower side is buried in the insulating resin layer.

5. The semiconductor package according to claim 4,
wherein the bonding wire connected to the semiconductor element on the lower side is insulated from the semiconductor element on an upper side by the insulating resin layer.

6. The semiconductor package according to claim 1,
wherein the semiconductor element constituting the second element group has a shape which is smaller than the semiconductor element constituting the first element group.

7. The semiconductor package according to claim 1,
wherein the first element group has a memory element as the semiconductor element, and the second element group has a controller element as the semiconductor element.

8. A semiconductor package, comprising:
a package base including a circuit board having a first connection pad formed on a front surface, a second connection pad formed on a back surface, and a wiring network connected to the first and second connection pads, a first element mounting part provided on the front surface side of the circuit board, a second element mounting part provided on the back surface side of the circuit board, and external connection terminals having metal bumps which are provided on the back surface of the circuit board to surround the second element mounting part and are connected to at least part of the first and second connection pads via the wiring network;
a first element group which is mounted on the first element mounting part of the package base, and has a first semiconductor element electrically connected to the first connection pad via a first bonding wire, and a second semiconductor element stacked on the first semiconductor element and electrically connected to the first connection pad via a second bonding wire; and
a second element group which is mounted on the second element mounting part of the package base, and has a third semiconductor element electrically connected to the second connection pad via a third bonding wire, and a fourth semiconductor element stacked on the third semiconductor element and electrically connected to the second connection pad via a fourth bonding wire.

9. The semiconductor package according to claim 8,
wherein the first semiconductor element and the second semiconductor element, and the third semiconductor element and the fourth semiconductor element are respectively bonded via insulating resin layers.

10. The semiconductor package according to claim 9,
wherein the first semiconductor element and the second semiconductor element, and the third semiconductor element and the fourth semiconductor element have substantially the same shapes respectively, and the insulating resin layers are charged between the first semiconductor element and the second semiconductor element, and between the third semiconductor element and the fourth semiconductor element, respectively.

11. The semiconductor package according to claim 10,
wherein element side end portions of the first and third bonding wires are buried in the insulating resin layers.

12. The semiconductor package according to claim 11,
wherein the first and third bonding wires are spaced from lower surfaces of the second semiconductor element and the fourth semiconductor element based on the thicknesses of the insulating resin layers, respectively.

13. The semiconductor package according to claim 10,
wherein the insulating resin layer has a first resin layer disposed on a side of the first semiconductor element or the third semi conductor element and softened or melted at a bonding temperature, and a second resin layer disposed on a side of the second semiconductor element or the fourth semiconductor element and kept in a layer shape against the bonding temperature.

14. The semiconductor package according to claim 13,
wherein the first and third bonding wires are spaced from lower surfaces of the second semiconductor element and the fourth semiconductor element via the second resin layers, respectively.

15. A semiconductor package, comprising:
a package base including a circuit board having a first connection pad formed on a front surface, a second connection pad formed on a back surface, and a wiring network connected to the first and second connection pads, a first element mounting part provided on the front surface side of the circuit board, a second element mounting part provided on the back surface side of the circuit board, and external connection terminals having metal bumps which are provided on the back surface of the circuit board to surround the second element mounting part and are connected to at least part of the first and second connection pads via the wiring network;
a first element group which is mounted on the first element mounting part of the package base, and has at least one semiconductor element electrically connected to the first connection pad; and
a second element group which is mounted on the second element mounting part of the package base, and has a semiconductor element electrically connected to the second connection pad and smaller than the semiconductor element constituting the first element group.

16. The semiconductor package according to claim 15,
wherein the first element group has a memory element as the semiconductor element, and the second element group has a controller element as the semiconductor element.

17. The semiconductor package according to claim 15,
wherein the first element group has a plurality of the semiconductor elements which are stacked.

18. The semiconductor package according to claim 17,
wherein the plurality of the stacked semiconductor elements are bonded to each other via an insulating resin layer.

19. The semiconductor package according to claim 18
wherein the plurality of semiconductor elements are electrically connected to the first connection pad via bonding wires respectively, and an element side end portion of the bonding wire connected to the semiconductor element on a lower side is buried in the insulating resin layer.

20. The semiconductor package according to claim 19,
wherein the bonding wire connected to the semiconductor element on the lower side is insulated from the semiconductor element on an upper side by the insulating resin layer.
